(19) United States
(12) Patent Application Publication
(10) Pub. No.: US 2013/0142478 A1
(43) Pub. Date: Jun. 6, 2013

(54) METHOD AND APPARATUS FOR ALIGNING A LASER DIODE ON A SLIDER STRUCTURE

(71) Applicants: David A. Sluzewski, Edina, MN (US); Scott E. Olson, Eagan, MN (US)

(72) Inventors: David A. Sluzewski, Edina, MN (US); Scott E. Olson, Eagan, MN (US)

(73) Assignee: SEAGATE TECHNOLOGY LLC, Cupertino, CA (US)

(21) Appl. No.: 13/310,446

(22) Filed: Dec. 2, 2011

(51) Int. Cl. G02B 6/42; H01L 21/66

(52) U.S. Cl. 385/14; 438/15; 257/E21.53

(57) ABSTRACT

An apparatus includes a slider structure having a top surface and a bottom surface opposite from the top surface. The apparatus includes a waveguide with an input facet at the top surface and an output proximate the bottom surface. A laser having an output facet is positioned proximate the input facet of the waveguide and include a second plurality of pads facing a first plurality of pads on the top surface of the slider. A bonding material is disposed between individual ones of the first and second plurality of pads such that a reflow of the bonding material induces relative movement between the laser and the top surface to align the input and output facets.

### SUMMARY

Various embodiments described herein are generally directed to methods, systems, and apparatuses that facilitate aligning a laser diode on a slider structure. In one embodiment, an apparatus comprises a slider structure, a laser, and a bonding material. The slider structure includes a top surface and a bottom surface opposite from the top surface, wherein the slider structure includes a waveguide having an input facet at the top surface and an output proximate the bottom surface, and wherein the slider structure includes a first plurality of pads on the top surface. The laser comprises an output facet positioned proximate the input facet of the waveguide, wherein the laser further includes a second plurality of pads facing the first plurality of pads. The bonding material is disposed between individual ones of the first and second plurality of pads such that a reflow of the bonding material induces relative movement between the laser and the top surface to align the input and output facets.

In another embodiment, a method comprises disposing a bonding material between a first plurality of pads on a top surface of a slider and a second plurality of pads of a laser, wherein the top surface is opposite a bottom surface of the slider. The laser is positioned on the top surface of the slider such that an output facet of the laser is proximate to an input facet of a waveguide of the slider at the top surface. The bonding material is reflowed to induce relative movement between the laser and the top surface to align the input and output facets.

These and other features and aspects of various embodiments may be understood in view of the following detailed discussion and accompanying drawings.

### BRIEF DESCRIPTION OF THE DRAWINGS

The discussion below makes reference to the following figures, wherein the same reference number may be used to identify the similar/same component in multiple figures.

FIG. 1 is a cross sectional view of a laser diode aligned on a recording head according to an example embodiment;

FIG. 2 is a top view of a recording head showing a plurality of pads on the top side of the recording head according to an example embodiment;

FIGS. 3A and 3B are cross sectional and bottom views of a laser diode according to an example embodiment;

FIGS. 4A-4C are schematic diagrams illustrating a passively aligned assembly of a laser diode to an optical coupler in a recording head according to an example embodiment;

FIG. 5 illustrates various processes for passively aligning a laser diode to a waveguide on a slider in accordance with various embodiments; and

FIG. 6 shows various processes for passively aligning a laser diode to a waveguide on a slider in accordance with other embodiments;

### DETAILED DESCRIPTION

The present disclosure is generally directed to recording heads used in magnetic recording devices such as hard drives. In particular, this disclosure relates to heat assisted magnetic recording (HAMR), which is one technique used to increase areal data density of magnetic media. HAMR generally refers to the concept of temporarily and locally heating a recording media to reduce the coercivity of the media so that an applied magnetic writing field can more easily direct the magnetization of the media during the temporary magnetic softening of the media caused by the heat source. A tightly confined, high power laser light spot can be used to heat a portion of the recording media. The heated portion is subjected to a magnetic field that sets the direction of magnetization of the heated portion. This approach to magnetic recording may also be referred to by other names, as thermal assisted magnetic recording (TAMR). Also, similar approaches may be used in other types of data recording, such as in magneto-optical (MO) systems.

In a HAMR device, optical guiding and focusing elements may be integrated in a recording head (also referred to as a “slider”) to couple the output of a laser light to the recording location and confine the laser light to a small spot on the media. One method of coupling laser light into these optical elements is to include a laser diode on the recording head itself and direct the laser diode output into an optical coupler of a waveguide on the recording head. The waveguide transmits the light to a small spot adjacent to an air bearing surface of the slider. To achieve efficient optical coupling and small resultant spot size, both the laser diode and the optical coupler may be single mode, which in turn requires that the laser and the optical coupler are aligned to sub-micron precision.

Active alignment can be used to achieve this precise alignment of single mode devices. Active alignment involves positioning the laser proximate to the waveguide with the laser output on and monitoring the coupled laser power while moving the laser to final position, after which the laser is attached (e.g., soldered) in place. Active alignment may be an expensive approach for mass production of hard drives and other devices. An alternative to active alignment is passive alignment method, which involves alignment and attachment with the laser off.

Another issue related to integrating a laser diode with a slider involves management of heat generated by the laser. A laser diode integrated with a recording head can experience adverse heating of the laser diode, reducing its performance and reliability. Using laser diodes with longer cavity lengths is one way to help to mitigate this heating problem. A longer cavity length increases the thermal connection from the recording head to the laser and lowers the current density needed to give sufficient output power for heating a magnetic recording media. Placing the laser diode on a surface of the recording head opposite from the media (hereinafter referred to as the “top surface”) provides a large mounting and heat sink area for the laser, and helps mitigate the adverse effects associated with excessive heat in the laser.

In a top surface mounting configuration, the laser and recording head may include features to route the laser emission toward the media. One of these features may include a mirror integrated within a surface emitting laser (SEL) that directs the emission out of the surface of the laser. The emissions are directed to a waveguide integrated within the recording head that directs the emissions to the media surface. Previous implementations having a top surface mounted SEL have utilized active alignment to maximize coupling efficiency between the laser and the waveguide, or used passive alignment at the expense of coupling efficiency. The embodiments described below include features that can increase coupling efficiency over previous passive alignment implementations.

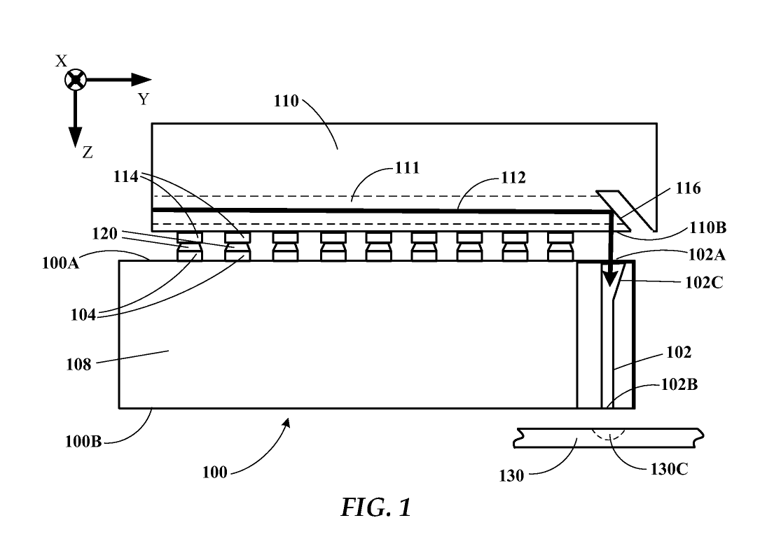

FIG. 1 is a cross-sectional view of an example of a slider for use in heat assisted magnetic recording (HAMR) according to various embodiments. The slider 100 includes a main recording head body 108, a top surface 100A, a bottom surface 100B (also referred to as an “air bearing surface” or a “media reading surface”) opposite from the top surface 100A, and a waveguide 102. A laser diode 110 (or shortly referred to as “laser”) is positioned on the slider to direct an emission of a laser light 112 into an input facet 102A of the waveguide, with the help of an integrated mirror 116 on the laser diode 110. The integrated mirror 116 directs the emission of a laser light 112 toward the top surface 100A. The light 112 then passes through the waveguide 102 that includes an optical coupler 102C. The light 112 travels through the waveguide 102 until it exits the air bearing surface 100B. The light 112 heats a portion 130C of a storage media 130 that is positioned adjacent to an output facet 102B of the waveguide. The input facet 102A of the waveguide 102 is at the top surface 100A of the slider, and the output facet 102B is proximate the air bearing surface 100B of the slider.

An output facet 110B of the laser diode 110 is positioned proximate to the input facet 102A of the waveguide and is aligned therewith to achieve efficient coupling of the light 112 from the laser diode 110 to the waveguide 102. A first plurality of pads 104 are positioned on the top surface 100A of the slider, and a second plurality of pads 114 are positioned on the laser. Between individual pads of the first and second plurality of pads, there is a bonding material 120 (e.g., solder) disposed such that a reflow of the bonding material 120 induces relative movement between the laser 110 and the top surface 100A to align the input facet 102A and the output facet 110B.

In accordance with FIG. 1, the laser diode 110 is placed on the top surface 100A of the recording head opposite from the storage media 130 to give a large area on which to place the laser 110. The laser 110 may include a long horizontal cavity 111, through which the laser light 112 is shown being routed before being reflected by integrated mirror 116. The mirror 116 directs the laser emissions toward the storage media 130 via the air bearing surface 100B. Using a laser diode with a long horizontal cavity 111 helps to mitigate adverse heating, and lowers the current density needed to give sufficient output power for heating a media relative to a vertical cavity. According to various embodiments, the laser 110 does not include a cavity. The alignment is achieved passively with the laser powered off by reflowing the bonding material 120 to induce relative movement between the laser 110 and the top surface 100A of the slider. This relative motion precisely aligns the output facet 110B of the laser with the input facet 102A of the waveguide.

According to one embodiment, the laser 110 is configured as a horizontal cavity surface emitting laser (SEL) that includes an integrated mirror 116 to direct the emission of the laser light 112 toward the air bearing surface 100B. The second plurality of pads 114 may include matching metal patterns on the laser 110 such that the patterns are aligned to the output facet 110B of the laser 110 and the integrated mirror 116. A first plurality of pads 104 may include matching metal patterns on the top surface 100A of the slider such that the patterns are aligned to the input facet 102A of the waveguide 102.

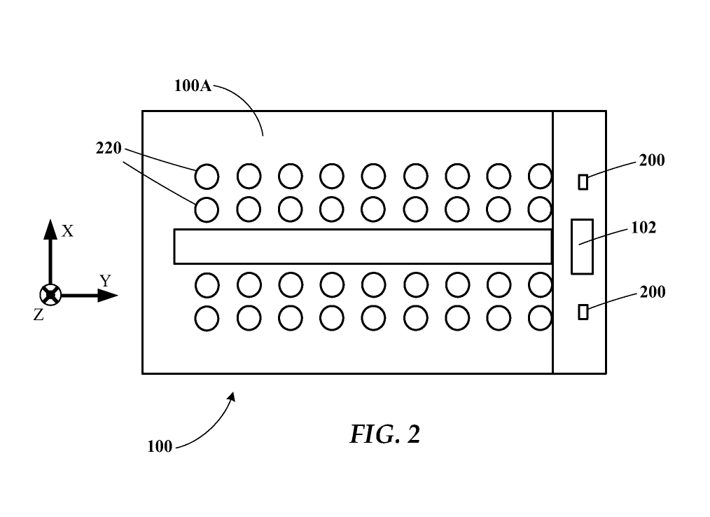

FIG. 2 is a top view of an example of a portion of a slider 100. A bonding material 220 is disposed on each of the plurality of pads 104 on the top surface 100A of the slider. According to various embodiments, bonding material 220 includes a solder pattern that matches the first plurality of pads 104 on the top surface and the second plurality of pads 114 on the laser. Modern photolithographic methods can be used to align a metal pattern 104 on the top surface 100A of the slider to the waveguide 102 on its edge, and also align the bonding material 220 to the waveguide 102. Fiducial marks 200 are positioned on an edge of the slider, and the fiducial marks 200 are referenced to the waveguide 102 and align a photomask to submicron precision. The aligned photomask helps to align the plurality of pads 104 and the bonding material 220 on the top surface 100A to the waveguide 102.

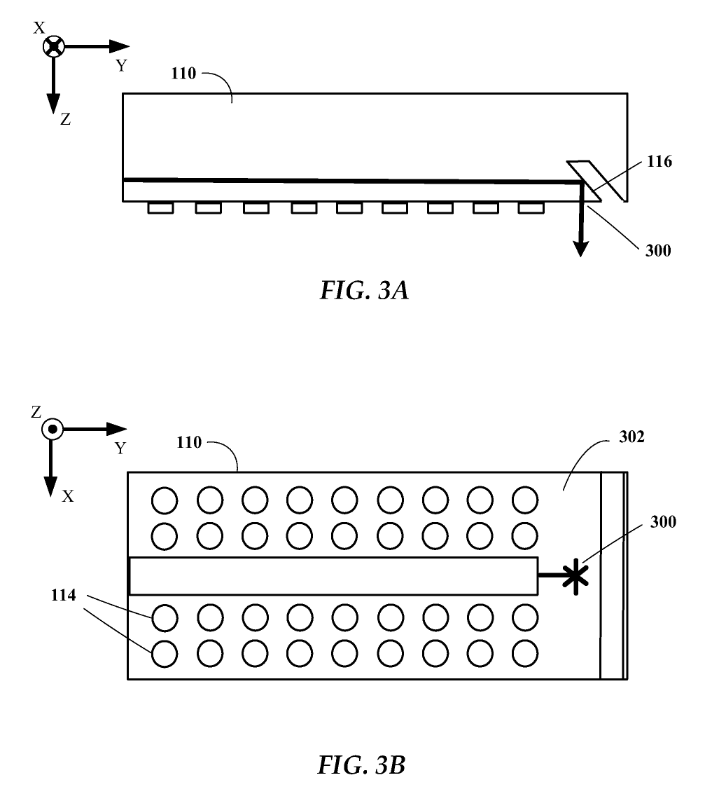

FIG. 3A is a cross-section view of a portion of laser 110, and FIG. 3B is a bottom view of a portion of laser 110. According to various embodiments, the laser is a surface emitting laser (SEL) and the second plurality of pads 114 are positioned on a bottom surface 302 of the SEL. The pads 114 include matching metal patterns that are precisely aligned to an output facet 300 of the laser 110 and an etch mask for the mirror 116. The mirror 116 is integrated with the laser such that it is easy for the mirror to align with the other elements of the laser 110. According to various embodiments, fiducial marks can be positioned on an edge of the laser 110, wherein the fiducial marks are referenced to the output facet 300 of the laser light and to the integrated mirror 116. A photomask can be used to help aligning the second plurality of pads 114 to the output facet 300 of the laser light and to the integrated mirror 116 by reference of the fiducial marks.

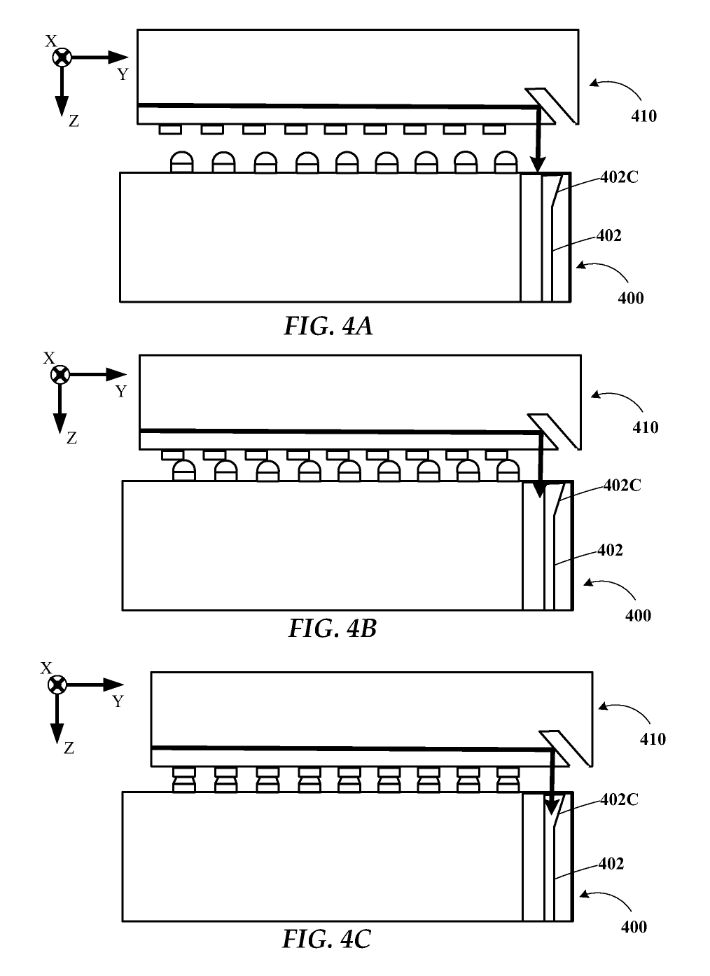

In reference now to FIGS. 4A to 4C, steps are shown for aligning a laser 410 and a waveguide 402 on a slider 400. This alignment generally involves using surface tension forces of liquid solder to passively bring matching metallic patterns on the slider and the laser into alignment to submicron precision, and without applying power to the laser. In order to achieve efficient optical coupling or alignment and small resultant spot size, both the laser 410 and the optical coupler 402C of the waveguide 402 may be single mode devices. In FIGS. 4A and 4B, the laser 410 and the slider 400 are roughly aligned prior to attach. This can be achieved, for example, with a pick-and-place machine. In FIG. 4B, the bonding material and the first plurality and second plurality of pads or the matching patterns are brought into contact.

In FIG. 4C, the solder pattern is heated above reflow temperature and a surface tension of the liquid solder brings the matching patterns into alignment. This alignment of the patterns also brings the laser 410 into alignment with the waveguide 402 on the slider 400. While the horizontal alignment in X and Y directions are fulfilled during the reflow, this arrangement may be relatively insensitive to the misalignment along Z direction, so long as such misalignment does not affect aiming of the laser's output with the waveguide 402. For example, a uniform vertical spacing (e.g., separation between the two in the Z direction) between the laser 410 and the slider 400 may be allowed to vary by a relatively large amount without affecting coupling efficiency of the laser to the slider. This may also allow for some non-uniformity of this vertical spacing, so long as the laser 410 is not tilted to such an extent that the laser's output is misaligned from the input to the waveguide 402.

The design of the apparatus comprising a laser and a slider according to various embodiments can achieve high manufacturing yields for the apparatus. The direction of the laser light, the alignment and location of bonding pads, etc., may be examined during pre-test to screen out bad laser or sliders before alignment. After alignment and reflow, a retest can confirm alignment of the laser. This retest can occur immediately after reflow, e.g., on a wafer or portion thereof that includes multiple slider assemblies, or on the individual sliders. The retest can occur at a later phase of manufacture, e.g., at the Head Gimbal Assembly (HGA) level. Rework may be possible at any of the stages following reflow.

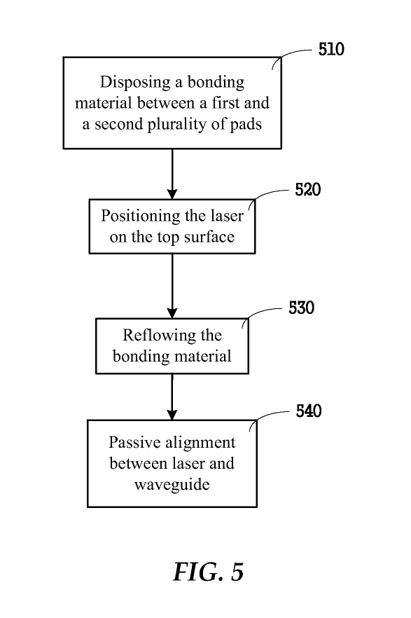

FIG. 5 illustrates a process for passively aligning 540 a laser to a waveguide on a slider in accordance with various embodiments. The process involves disposing 510 a bonding material between a first plurality of pads on a top surface of a slider and a second plurality of pads of a laser, wherein the top surface is opposite a bottom surface of the slider. The bottom surface may be configured as an air bearing surface, which is a surface close to a media during reading or writing. According to various embodiments, both the first plurality of pads and the second plurality of pads comprise matching metal patterns, and the laser and the waveguide both comprise single mode devices. The process further involves positioning 520 the laser on the top surface of the slider such that an output facet of the laser is proximate to an input facet of a waveguide of the slider at the top surface. The process further involves reflowing 530 the bonding material to induce relative movement between the laser and the top surface to align the input facet of the waveguide and the output facet of the laser.

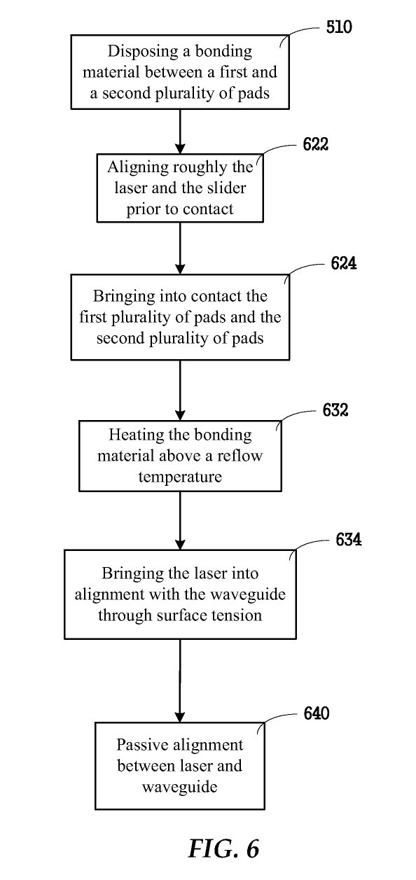

FIG. 6 shows a process for passively aligning 640 a laser to a waveguide on a slider in accordance with another embodiment. According to the embodiment shown in FIG. 6, after disposing 510 a bonding material between the first and second plurality of pads, the process involves roughly aligning 622 the laser and the slider prior to contact between them, e.g., using a pick-and-place machine. According to various embodiments, the laser includes a surface emitting laser (SEL) and comprises an integrated mirror directing an emission out of the laser toward the input facet of the waveguide. The laser and the waveguide may both comprise single mode devices. The process further involves bringing 624 the first plurality of pads into contact with the second plurality of pads, through the bonding material. Both the first and the second plurality of pads comprise matching metal patterns in accordance with various embodiments.

The process in FIG. 6 further involves heating 632 the bonding material above a reflow temperature and bringing 634 the laser into alignment with the waveguide on the slider through surface tension. Once the bonding material (e.g., solder pattern) is heated above a reflow temperature, it becomes a fluid which induces surface tension to bring the matching metal patterns into alignment. Since the matching metal patterns have been aligned to the laser and the waveguide before during fabrication, surface tension also brings the laser into alignment with the waveguide on the slider. According to various embodiments, the process can further involve building fiducial marks on an edge of the slider referenced to the waveguide and align an photomask to submicron precision, and building fiducial marks on an edge of the laser referenced to the output facet of the laser and the etch mask for the integrated mirror.

The foregoing description of the example embodiments has been presented for the purposes of illustration and description. It is not intended to be exhaustive or to limit the inventive concepts to the precise form disclosed. Many modifications and variations are possible in light of the above teaching. Any or all features of the disclosed embodiments can be applied individually or in any combination are not meant to be limiting, but purely illustrative. It is intended that the scope be limited not with this detailed description, but rather determined by the claims appended hereto.

What is claimed is:

1. An apparatus comprising:
a slider structure including a top surface and a bottom surface opposite from the top surface, wherein the slider structure includes a waveguide having an input facet at the top surface and an output proximate the bottom surface, and wherein the slider structure includes a first plurality of pads on the top surface;
a laser having an output facet positioned proximate the input facet of the waveguide, wherein the laser further includes a second plurality of pads facing the first plurality of pads; and
a bonding material disposed between individual ones of the first and second plurality of pads such that a reflow of the bonding material induces relative movement between the laser and the top surface to align the input and output facets.

2. The apparatus of claim 1, wherein the laser comprises an integrated mirror directing an emission toward the bottom surface.

3. The apparatus of claim 1, wherein the laser is a horizontal cavity surface emitting laser.

4. The apparatus of claim 1, wherein the second plurality of pads comprises matching metal patterns on the laser such that the patterns are aligned to the output facet of the laser and the integrated mirror.

5. The apparatus of claim 1, wherein the first plurality of pads comprises matching metal patterns on the top surface of the slider such that the patterns are aligned to the input facet of the waveguide.

6. The apparatus of claim 1, further comprising fiducial marks on an edge of the slider, wherein the fiducial marks are referenced to the waveguide and align a photomask to submicron precision.

7. The apparatus of claim 1, further comprising fiducial marks on an edge of the laser, wherein the fiducial marks are referenced to the output facet of the laser and to the integrated mirror.

8. The apparatus of claim 1, wherein the laser is aligned with the waveguide using passive alignment.

9. The apparatus of claim 1, wherein the laser and an optical coupler of the waveguide both comprise single mode devices.

10. The apparatus of claim 1, wherein the bonding material comprises a solder pattern with a surface tension of liquid solder force to match the second plurality of pads on the laser and the first plurality of pads on the top surface.

11. The apparatus of claim 1, wherein coupling efficiency between the laser and the waveguide is insensitive to vertical spacing between the laser and the slider structure.

12. A method comprising:
disposing a bonding material between a first plurality of pads on a top surface of a slider and a second plurality of pads of a laser, wherein the top surface is opposite a bottom surface of the slider;
positioning the laser on the top surface of the slider such that an output facet of the laser is proximate to an input facet of a waveguide of the slider at the top surface; and
reflowing the bonding material to induce relative movement between the laser and the top surface to align the input and output facets.

13. The method of claim 12, wherein positioning the laser on the top surface comprises:
aligning roughly the laser and the slider prior to contact between the laser and the slider; and
bringing into contact the first plurality of pads and the second plurality of pads.

14. The method of claim 12, wherein reflowing the bonding material comprises:
heating the bonding material above a reflow temperature; and
bringing the laser into alignment with the waveguide on the slider through surface tension.

15. The method of claim 12, wherein the laser comprises a surface emitting laser (SEL) and comprises an integrated mirror directing an emission out of the laser toward the input facet of the waveguide.

16. The method of claim 12, wherein both the first plurality of pads and the second plurality of pads comprise matching metal patterns.

17. The method of claim 15, further comprising:
building fiducial marks on an edge of the slider referenced to the waveguide and align an photomask to submicron precision; and
building fiducial marks on an edge of the laser referenced to the output facet of the laser and the etch mask for the integrated mirror.

18. The method of claim 12, wherein the laser and an optical coupler of the waveguide both comprise single mode devices.

19. An article of manufacture prepared by a process comprising:
disposing a bonding material between a first plurality of pads on a top surface of a slider and a second plurality of pads of a laser, wherein the top surface is opposite a bottom surface of the slider;
positioning the laser on the top surface of the slider such that an output facet of the laser is proximate to an input facet of a waveguide of the slider at the top surface; and
reflowing the bonding material to induce relative movement between the laser and the top surface to align the input and output facets.

20. The article of manufacture of claim 19, wherein coupling efficiency between the laser and the waveguide is insensitive to vertical spacing between the laser and the slider structure.
